(19) United States
(12) Patent Application Publication
(10) Pub. No.: US 2026/0164693 A1
(43) Pub. Date: Jun. 11, 2026

(54) MANUFACTURING METHOD OF A SEMICONDUCTOR MEMORY DEVICE

(71) Applicant: SK hynix Inc., Icheon-si Gyeonggi-do (KR)

(72) Inventors: Na Yeong YANG, Icheon-si Gyeonggi-do (KR); Rho Gyu KWAK, Icheon-si Gyeonggi-do (KR); Jung Shik JANG, Icheon-si Gyeonggi-do (KR); Seok Min CHOI, Icheon-si Gyeonggi-do (KR); Won Geun CHOI, Icheon-si Gyeonggi-do (KR)

(73) Assignee: SK hynix Inc., Icheon-si Gyeonggi-do (KR)

(21) Appl. No.: 19/182,157

(22) Filed: Apr. 17, 2025

(30) Foreign Application Priority Data
Oct. 31, 2024 (KR) 10-2024-0152946

(51) Int. Cl. H10D 30/01; G11C 16/04; H10B 41/10; H10B 41/27; H10B 41/35; H10B 41/41; H10B 41/42; H10B 41/50; H10B 43/10; H10B 43/27; H10B 43/35; H10B 43/40; H10B 43/50; H10D 30/68; H10D 30/69; H10W 80/00; H10W 90/00

(52) U.S. Cl. CPC H10D 30/0411; G11C 16/0483; H10B 41/42; H10D 30/0413; H10B 41/10; H10B 41/27; H10B 41/35; H10B 41/41; H10B 41/50; H10B 43/10; H10B 43/27; H10B 43/35; H10B 43/40; H10B 43/50; H10D 30/689; H10D 30/693; H10W 80/312; H10W 90/792

(57) ABSTRACT

A method of manufacturing a semiconductor memory device includes forming an insulating layer, forming a preliminary stack by alternately stacking first material layers and second material layers over a surface of the insulating layer in a stacking direction, forming a mask pattern over the preliminary stack, the mask pattern including a first opening, a second opening, and a plurality of grooves disposed around the first opening, forming a first hole and a second hole to different depths toward the insulating layer in a direction opposite to the stacking direction by etching the preliminary stack with the plurality of grooves blocked, and etching the preliminary stack through the first hole and the second hole with the plurality of grooves, the first opening, and the second opening opened so that the first hole and the second hole are extended deeper toward the insulating layer.

### CROSS-REFERENCE TO RELATED APPLICATION

The present application claims priority under 35 U.S.C. § 119(a) to Korean patent application number 10-2024-0152946 filed on Oct. 31, 2024, in the Korean Intellectual Property Office, the entire disclosure of which application is incorporated herein by reference.

### BACKGROUND

### 1. Technical Field

Various embodiments of the present disclosure generally relate to a method of manufacturing a semiconductor memory device, and more particularly, to a method of manufacturing a three-dimensional semiconductor memory device.

### 2. Related Art

Semiconductor memory devices are applicable not only to small electronic devices, but also to electronic systems in various fields, such as automobiles, medical care, and data centers. As a result, the demand for semiconductor memory devices is increasing.

Semiconductor memory devices include memory cells for data storage. A three-dimensional semiconductor memory device includes a plurality of memory cells arranged in three dimensions. Thus, the three-dimensional semiconductor memory device is more advantageous for increasing capacity as compared to a two-dimensional semiconductor memory device.

The degree of integration of memory cells in the three-dimensional semiconductor memory device may be improved by increasing the number of memory cells stacked on top of each other. When the number of stacked memory cells is increased, the number of stacked conductive layers coupled to the memory cells is increased. The conductive layers are respectively coupled to gate contact plugs and are electrically coupled to a peripheral circuit through the gate contact plugs. However, the increase in the number of stacked conductive layers may result in deterioration in process stability and operation reliability of the semiconductor memory device.

### SUMMARY

According to an embodiment, a method of manufacturing a semiconductor memory device may include: forming a first insulating layer; forming a preliminary stack by alternately stacking over a surface of the first insulating layer in a stacking direction second insulating layers of a plurality of second insulating layers with sacrificial layers of a plurality of sacrificial layers; forming a mask pattern over the preliminary stack, the mask pattern including a plurality of first openings, a plurality of second openings, a plurality of third openings, and a plurality of grooves disposed around the plurality of first openings; forming a first group of a plurality of holes exposing an uppermost sacrificial layer among the sacrificial layers by etching the preliminary stack through the plurality of first openings, the plurality of second openings, and the plurality of third openings; forming a second group of a plurality of holes respectively corresponding to the plurality of first openings, the plurality of second openings, and the plurality of third openings, the plurality of holes in the second group having different depths toward the first insulating layer in an opposite direction to the stacking direction by repeatedly performing an etching process on the preliminary stack with the plurality of grooves blocked; and forming a third group of a plurality of holes by etching the preliminary stack with the plurality of grooves opened and one or more of the plurality of holes in the second group opened through the plurality of first openings and the plurality of second openings.

According to an embodiment, a method of manufacturing a semiconductor memory device may include: forming an insulating layer; forming a preliminary stack by alternately stacking first material layers of a plurality of first material layers with second material layers of a plurality of second material layers over a surface of the insulating layer in a stacking direction; forming a mask pattern over the preliminary stack, the mask pattern including a first opening, a second opening, and a plurality of grooves disposed around the first opening; forming a first hole and a second hole to different depths toward the insulating layer in an opposite direction to the stacking direction by etching the preliminary stack through the first opening and the second opening with the plurality of grooves blocked; and etching the preliminary stack through the first hole and the second hole with the plurality of grooves, the first opening, and the second opening opened so that the first hole and the second hole are extended deeper toward the insulating layer.

### BRIEF DESCRIPTION OF THE DRAWINGS

FIG. 1 is a block diagram illustrating an electronic system including a semiconductor memory device according to an embodiment of the present disclosure;

FIG. 2 is a circuit diagram illustrating a memory cell array of a semiconductor memory device according to an embodiment of the present disclosure;

FIGS. 3A and 3B are diagrams illustrating a semiconductor memory device according to embodiments of the present disclosure;

FIGS. 4A and 4B are a plan view and a cross-sectional view illustrating a semiconductor memory device according to an embodiment of the present disclosure;

FIGS. 5A and 5B are a plan view and a cross-sectional view showing a preliminary stack, a cell pillar, and a mask layer according to an embodiment of the present disclosure;

FIGS. 6A and 6B are a plan view and a cross-sectional view showing a first photoresist pattern and a mask pattern according to an embodiment of the present disclosure;

FIGS. 7A, 7B, 7C, 7D, 7E, and 7F are cross-sectional views illustrating a plurality of holes and a plurality of sacrificial pillars according to an embodiment of the present disclosure;

FIGS. 8A and 8B are a plan view and a cross-sectional view showing a gate stack according to an embodiment of the present disclosure;

FIGS. 9A and 9B are cross-sectional views illustrating a plurality of contact holes and a plurality of contact pillars according to an embodiment of the present disclosure;

FIGS. 10A and 10B are a plan view and a cross-sectional view showing a first photoresist pattern and a mask pattern according to an embodiment of the present disclosure; and

FIG. 11 is a cross-sectional view showing a first photoresist pattern and a mask pattern according to an embodiment of the present disclosure.

### DETAILED DESCRIPTION

Specific structural or functional descriptions of examples of embodiments in accordance with concepts which are disclosed in this specification are illustrated only to describe the examples of embodiments in accordance with the concepts and the examples of embodiments in accordance with the concepts may be carried out by various forms but the descriptions are not limited to the examples of embodiments described in this specification.

Terms such as “first,” “second,” etc., are used to distinguish between various elements and do not imply size, order, priority, quantity, or importance of the elements. For example, a first element may be named as a second element in one example, and the second element may be named as a first element in another example. Terms such as “top,” “over,” “on,” “side,” “upper,” “lower,” “row,” “column,” “inner,” “outer” and other terms implying relative spatial relationships or orientations are utilized only for the purpose of ease of description or reference to a drawing and are not otherwise limiting. The cross-hatching throughout the figures illustrates corresponding or similar areas between the figures rather than indicating the materials associated with the areas. It will be understood that when an element or layer etc., is referred to as being “on,” “connected to,” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present.

Various embodiments of the present disclosure provide a method of manufacturing a semiconductor memory device capable of improving process stability and operation reliability.

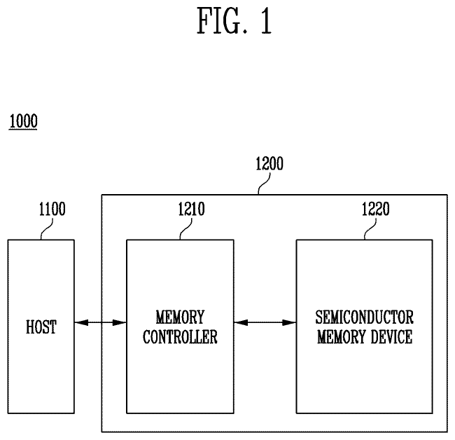

FIG. 1 is a block diagram illustrating an electronic system 1000 including a semiconductor memory device according to an embodiment of the present disclosure.

Referring to FIG. 1, the electronic system 1000 may be a computing system, a medical device, a communication device, a wearable device, a memory system, or the like. The electronic system 1000 may include a host 1100 and a storage device 1200.

The host 1100 may store data in the storage device 1200 or read data stored in the storage device 1200 based on an interface. The interface may include one or more of a Double Data Rate (DDR) interface, a Universal Serial Bus (USB) interface, a multimedia card (MC) interface, an embedded MMC (eMMC) interface, a peripheral component interconnection (PCI) interface, a PCI-express (PCI-E) interface, an Advanced Technology Attachment (ATA) interface, a Serial-ATA interface, a Parallel-ATA interface, a small computer system interface (SCSI), an enhanced small disk interface (ESDI), an Integrated Drive Electronics (IDE) interface, a Firewire interface, a Universal Flash Storage (UFS) interface, and a Nonvolatile Memory express (NVMe) interface.

The storage device 1200 may include a memory controller 1210 and a semiconductor memory device 1220. In an embodiment, the storage device 1200 may be a storage medium, such as a solid-state drive (SSD), a universal serial bus (USB) memory, or the like.

The memory controller 1210 may store data in the semiconductor memory device 1220 or read data stored in the semiconductor memory devices 1220 under the control of the host 1100.

The semiconductor memory device 1220 may include one memory chip or a plurality of memory chips. The semiconductor memory device 1220 may store data or output stored data under the control of the memory controller 1210.

The semiconductor memory device 1220 may be a non-volatile memory device. The semiconductor memory device 1220 may include a memory cell array and a peripheral circuit which controls operations of the memory cell array. The memory cell array may include a plurality of memory cells. Each memory cell may be a non-volatile memory cell. In an embodiment, each memory cell may be a NAND flash memory cell. Hereinafter, embodiments of the present disclosure are described based on a semiconductor memory device including a NAND flash memory cell, but the present teachings are not limited thereto. In another embodiment, each memory cell may be configured as a ferroelectric memory cell, a variable resistance memory cell, or the like.

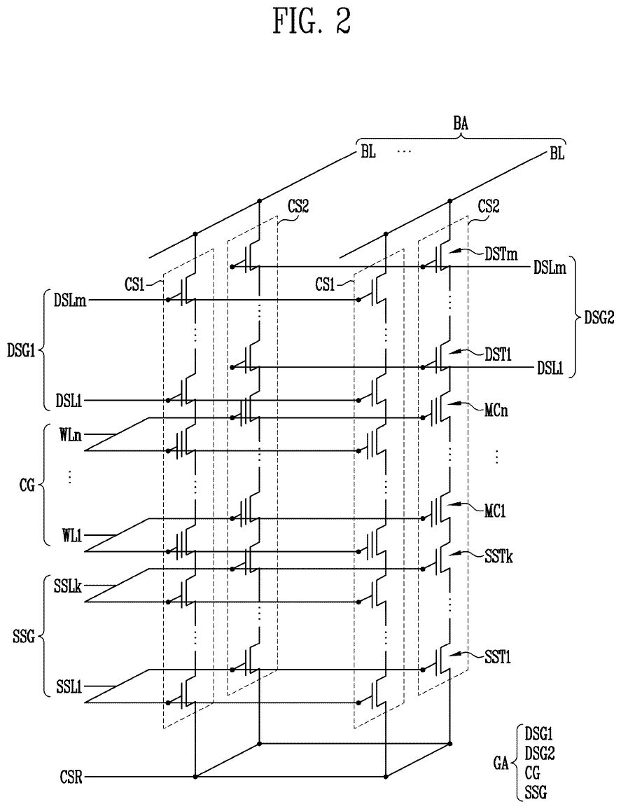

FIG. 2 is a circuit diagram illustrating a memory cell array of a semiconductor memory device according to an embodiment of the present disclosure.

Referring to FIG. 2, the memory cell array may include a plurality of memory cell strings CS1 and CS2. A plurality of memory cell strings CS1 and CS2 may constitute a memory block, and the memory block is electrically coupled to a peripheral circuit (not shown) through a gate array GA, a bit line array BA, and a common source layer CSR.

Each of the plurality of memory cell strings CS1 and CS2 includes at least one source select transistor (e.g., SST1), a plurality of memory cells MC1 to MCn (where n is a natural number greater than or equal to 2), and at least one drain select transistor (e.g., DST1). In an embodiment, each of the plurality of memory cell strings CS1 and CS2 may include a plurality of source select transistors SST1 to SSTk (where k is a natural number greater than or equal to 2 and less than n) coupled in series between the common source layer CSR and the plurality of memory cells MC1 to MCn, and a plurality of drain select transistors DST1 to DSTm (where m is a natural number greater than or equal to two and less than n) coupled in series between the bit line array BA and the plurality of the memory cells MC1 and MCn. The plurality of memory cells MC1 to MCn are coupled in series between the drain select transistor (for example, DST1) and the source select transistor (for example, SSTk).

The gate array GA includes at least one source select gate group (e.g., SSG), a cell gate group CG, and at least one drain select gate group (e.g., DSG1). In an embodiment, the gate array GA may include a first drain select gate group DSG1 and a second drain select gate group DSG2 which are coupled in a smaller unit than the cell gate group CG to the memory cell strings, and a source select gate group SSG coupled in an equal unit to the cell gate group CG to the memory cells strings. For example, the plurality of memory cell strings CS1 and CS2 may include a first memory cell string CS1 coupled to the first drain select gate group DSG1 and a second memory cell string CS2 coupled to the second drain select gate group DSG2. Each of the cell gate group CG and the source select gate group SSG may be coupled to the first memory cell string CS1 and may be extended to be coupled to the second memory cell string CS2.

The source select gate group SSG includes at least one source select line (e.g., SSL1). In an embodiment, the source select gate group SSG may include a plurality of source select lines SSL1 to SSLk. The plurality of source select lines SSL1 to SSLk are coupled to a plurality of gate electrodes of the plurality of source select transistors SST1 to SSTk, respectively.

The cell gate group CG may include a plurality of word lines WL1 to WLn. The plurality of word lines WL1 to WLn are coupled to a plurality of gate electrodes of the plurality of memory cells MC1 to MCn, respectively.

Each of the first and second drain select gate groups DSG1 and DSG2 includes at least one drain select line (e.g., DSL1). According to an embodiment, each of the first and second drain select gate groups DSG1 and DSG2 may include a plurality of drain select lines DSL1 to DSLm. The plurality of drain select lines DSL1 to DSLm are coupled to a plurality of gate electrodes of the plurality of drain select transistors DST1 to DSTm, respectively.

The bit line array BA includes a plurality of bit lines BL. The plurality of memory cell strings CS1 and CS2 may be divided into a plurality of columns coupled to the plurality of bit lines BL. In an embodiment, the memory cell strings of each column may be coupled to the bit line BL corresponding thereto. For example, a pair of the first memory cell string CS1 and the second memory cell string CS2 may be included in one column.

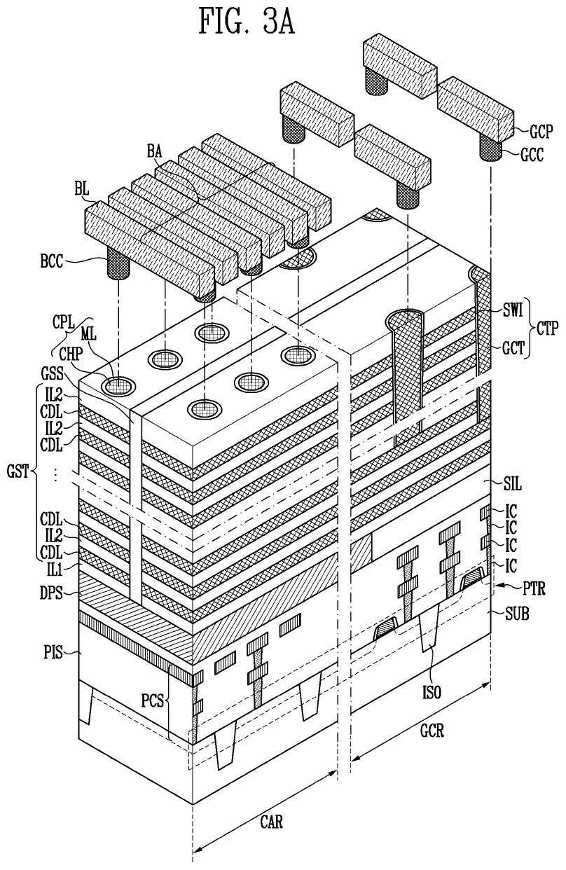

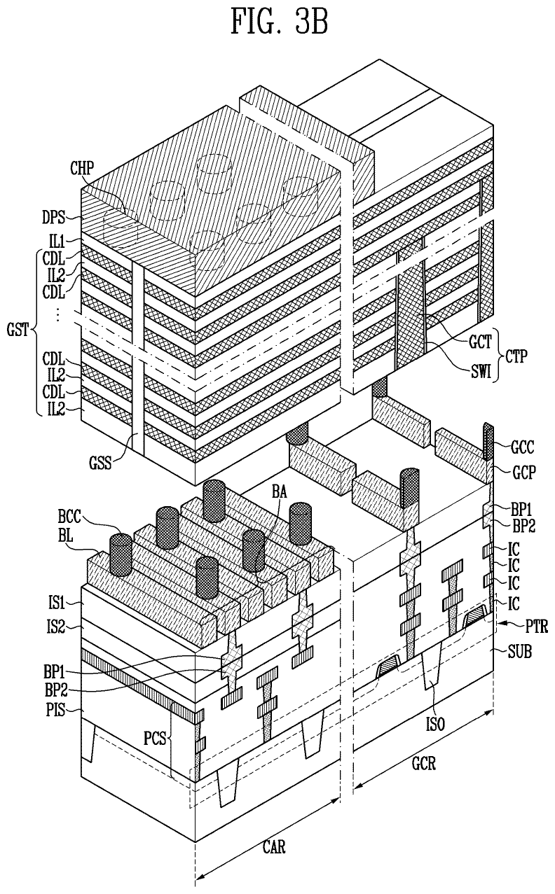

The gate array GA is electrically coupled to the peripheral circuit through the gate contact plug of the contact pillar. Hereinafter, the contact pillar is described with reference to FIGS. 3A and 3B.

FIGS. 3A and 3B are diagrams illustrating a semiconductor memory device according to embodiments of the present disclosure.

Referring to FIGS. 3A and 3B, a semiconductor memory device includes a peripheral circuit structure PCS, a doped semiconductor structure DPS, a plurality of gate stacks GST, the bit line array BA, a plurality of cell pillars CPL, and a plurality of contact pillars CTP. The doped semiconductor structure DPS, the plurality of gate stacks GST, the bit line array BA, the plurality of cell pillars CPL, and the plurality of contact pillars CTP are disposed over the peripheral circuit structure PCS.

The peripheral circuit structure PCS may include an input/output circuit, a control circuit, a voltage generation circuit, a row decoder, a column decoder, a page buffer, and the like. The peripheral circuit structure may include a plurality of transistors PTR constituting at least some of the above components and a plurality of interconnections IC coupled thereto. The plurality of transistors PTR may include pass transistors constituting a pass circuit.

Each transistor PTR is disposed in an active region of a semiconductor substrate SUB, and the active region is partitioned by an isolation layer ISO. The semiconductor substrates SUB include semiconductor materials. In an embodiment, the semiconductor material may include one or more of a group IV semiconductor, a group III-V compound semiconductor, and a group II-VI compound semiconductor. Group IV semiconductors may include single crystal silicon (Si), polycrystalline silicon, germanium (Ge), and silicon germanium (SiGe). Group III-V compound semiconductors may include GaAs, GaN, GaP, GaAsP, GaInAsP, AlAs, AlGa, InP, InSb, and InGaAs. Group II-VI compound semiconductors may include ZnS, ZnO, or CdS.

The semiconductor substrate SUB may further include a dielectric layer. In an embodiment, the semiconductor substrate SUB may be a silicon-on-insulator (SOI) substrate or a germanium-on-insulator (GeOI) substrate. The semiconductor substrate SUB may further include an organic material. In an embodiment, the semiconductor substrate SUB may include graphene.

The semiconductor substrate SUB may be a bulk wafer or an epitaxial layer grown by selective epitaxial growth (SEG). Alternatively, the semiconductor substrate SUB may be a layer formed by a Metal Induced Lateral Crystallization (MILC) method and may partially include metal.

The semiconductor substrate SUB may have a single crystalline, polycrystalline, or amorphous state. The semiconductor substrate SUB may include Group II, III, IV, V, or VI impurities. In an embodiment, the semiconductor substrate SUB may include an n-well region doped with n-type impurities, a p-well region doped with p-type impurities, or an n-well area and a p-well area.

The plurality of transistors PTR is covered by a peripheral insulation structure PIS on the semiconductor substrate SUB. The plurality of interconnections IC may be formed in the peripheral insulation structure PIS and include a plurality of conductive lines and a plurality of conductive contacts for electrical connection.

The semiconductor substrate SUB may include a cell array region CAR and a gate contact region GCR. The plurality of transistors PTR may be disposed in the cell array region CAR and the gate contact region GCR of the semiconductor substrate SUB. The plurality of transistors PTR may include pass transistors disposed in the gate contact region GCR.

The plurality of gate stacks GST is disposed between the bit line array BA and the doped semiconductor structure DPS. A first insulating layer IL1 is disposed between each of the gate stacks GST and the doped semiconductor structure DPS.

Each gate stack GST includes a plurality of conductive layers CDL. The plurality of conductive layers CDL are stacked spaced apart from each other over a surface of the first insulating layer IL1 opposite to the doped semiconductor structure DSP. Each of the plurality of conductive layers CDL may include various conductive materials, such as a doped semiconductor layer and a metal layer. The doped semiconductor layer may include a doped silicon layer. The metal layer may include tungsten, copper, molybdenum, or the like. Each of the plurality of conductive layers CDL may further include a metal nitride layer. The metal nitride layer may include titanium nitride, tantalum nitride, or the like. The plurality of conductive layers CDL may serve as the gate array GA, as shown in FIG. 2. The plurality of conductive layers CDL may serve as the source select gate group SSG, as shown in FIG. 2, the first and second drain select line groups DSG1 and DSG2, as shown in FIG. 2, and the cell gate group CG, as shown in FIG. 2. At least one layer adjacent to the doped semiconductor structure DPS among the plurality of conductive layers CDL may serve as the source select gate group SSG, as shown in FIG. 2. At least one of the plurality of conductive layers CDL adjacent to the bit line array BA may serve as the first and second drain select line groups DSG1 and DSG2, as shown in FIG. 2.

Each gate stack GST may further include a plurality of second insulating layers IL2. The plurality of second insulating layers IL2 may be arranged alternately with the plurality of conductive layers CDL. Each of the first insulating layer IL1 and the plurality of second insulating layers IL2 may include an insulating material, such as a silicon oxide layer or a silicon oxynitride layer.

Each of the first insulating layer IL1, the plurality of conductive layers CDL, and the plurality of second insulating layers IL2 is disposed on the cell array region CAR of the semiconductor substrate SUB and extends to be disposed on the gate contact region GCR of the semiconductor substrate SUB. A gate separation structure GSS may be disposed between adjacent gate stacks GST. The gate separation structure GSS may include a filler in a slit formed between adjacent gate stacks GST. The filler may be designed in a variety of ways. In an embodiment, the filler may include an insulating layer. In another embodiment, the filler may further include one or both of a conductive layer and a semiconductor layer in addition to the insulating layer.

The plurality of cell pillars CPL is disposed on the cell array region CAR of the semiconductor substrate SUB and penetrate each gate stack GST. The cell pillars CPL penetrate the first insulating layer IL1 to be in contact with the doped semiconductor structure DPS. Each of the plurality of conductive layers CDL and the plurality of second insulating layers IL2 may surround a sidewall of each cell pillar CPL. A cell pillar CPL includes a channel pillar CHP and a memory layer ML.

The channel pillar CHP may be electrically coupled to the corresponding bit line among the plurality of bit lines BL of the bit line array BA through a bit line connection structure BCC. The channel pillar CHP may include a contact surface in contact with the doped semiconductor structure DPS. The contact surface may be located on a part of the side wall of the channel pillar CHP, the end of the channel pillar CHP, etc. According to an embodiment, referring to FIG. 3B, the doped semiconductor structure DPS may include a groove into which the end of the channel pillar CHP is inserted, and a contact surface between the end of the channel pillar CHP and the doped semiconductor structures DPS may be formed along the groove.

The plurality of contact pillars CTP is disposed on the gate contact region GCR of the semiconductor substrate SUB. The contact pillars CTP are embedded in each gate stack GST. The contact pillars CTP are spaced apart from the first insulating layer IL1 at different distances and extend in a direction opposite to a direction toward the first insulating layer IL1. Each contact pillar CTP includes a gate contact plug GCT and a sidewall insulating layer SWI.

The gate contact plug GCT is a conductive pattern in contact with the corresponding conductive layer among the plurality of conductive layers CDL. The gate contact plugs GCT may include a variety of conductive materials. In an embodiment, the gate contact plug GCT may include a barrier layer and a metal layer. The barrier layer may include a conductive metal nitride layer, such as titanium nitride, tantalum nitride, or molybdenum nitride. The metal layer may include tungsten, molybdenum, or the like. The barrier layer may extend along the outer wall of the metal layer L4.

The sidewall insulating layer SWI surrounds the sidewall of the gate contact plug GCT. Some of the conductive layers which are penetrated by the gate contact plug GCT among the plurality of conductive layers CDL are insulated from the gate contact plug GCT by the sidewall insulating layer SWI.

One of the doped semiconductor structure DPS and the bit line array BA is disposed closer to the peripheral circuit structure PCS than the other. In an embodiment, as shown in FIG. 3A, the doped semiconductor structure DPS may be disposed closer to the peripheral circuit structure PCS than the bit line array BA. In another embodiment, as shown in FIG. 3B, the bit line array BA may be disposed closer to the peripheral circuit structure PCS than the doped semiconductor structure DPS.

Referring to FIGS. 3A and 3B, the doped semiconductor structure DPS may include at least one doped semiconductor layer. The doped semiconductor layer of the doped semiconductor structure DPS may include n-type impurities or p-type impurities. In an embodiment, the doped semiconductor structure DPS includes one or both of a first conductivity type doped semiconductor layer including n-type impurities as majority carriers and a second conductivity type doped semiconductor layer including p-type impurities as majority carriers. The first conductivity type doped semiconductor layer may serve as the common source layer CSR as described with reference to FIG. 1, and the second conductivity type doped semiconductor layer may serve as a well region.

Referring to FIG. 3A, the doped semiconductor structure DPS may be disposed between the peripheral insulating structure PIS and the gate stack GST. The doped semiconductor structure DPS may be penetrated by a source isolation insulating layer SIL. In an embodiment, the first insulating layer IL1 and the gate stack GST may overlap the doped semiconductor structure DPS and the source isolation insulating layer SIL. The gate contact plug GCT may be electrically coupled to a pass transistor among the plurality of transistors PTR through the gate contact connection structure GCC and a gate contact pad GCP. To this end, the semiconductor memory device may further include a conductive connection structure (not shown) for electrical connection between an interconnection corresponding to the pass transistor among the plurality of interconnections IC and the gate contact pad GCP.

Referring to FIG. 3B, the gate stack GST and the bit line array BA may be disposed between the doped semiconductor structure DPS and the peripheral circuit structure PCS. The semiconductor memory device may include the gate contact pad GCP disposed between the gate contact region GCR of the semiconductor substrate SUB and the gate stack GST, and a gate contact connection structure GCC disposed between the gate pad GCP and the gate contact plug GCT. The gate contact plug GCT may be electrically coupled to the gate contact pad GCP through the gate contact connection structure GCC.

Referring to FIG. 3B, the semiconductor memory device may include a plurality of first conductive bonding patterns BP1 and a plurality of second conductive bonding patterns BP2 disposed between the bit line array BA and the peripheral insulating structure PIS. The plurality of first conductive bonding patterns BP1 may be disposed in a first intervening insulating structure IS1. Each of the plurality of bit lines BL and the gate contact pad GCP may be coupled to the corresponding first conductive bonding pattern BP1 among the plurality of first conductive bonding patterns BP1. The plurality of second conductive bonding patterns BP2 may be disposed in a second intervening insulating structure IS2 between the first intervening insulating structures IS1 and the peripheral insulating structures PIS. Each of the plurality of second conductive bonding patterns BP2 may be coupled to the interconnection IC corresponding thereto. The plurality of second conductive bonding patterns BP2 may be bonded to the plurality of first conductive bonding patterns BP1. Accordingly, the gate contact plug GCT may be electrically coupled to a corresponding pass transistor among the plurality of transistors PTR through the gate contact connection structure GCC, the gate contact pad GCP, the first conductive bonding pattern BP1, the second conductive bonding pattern BP2, and the interconnection IC.

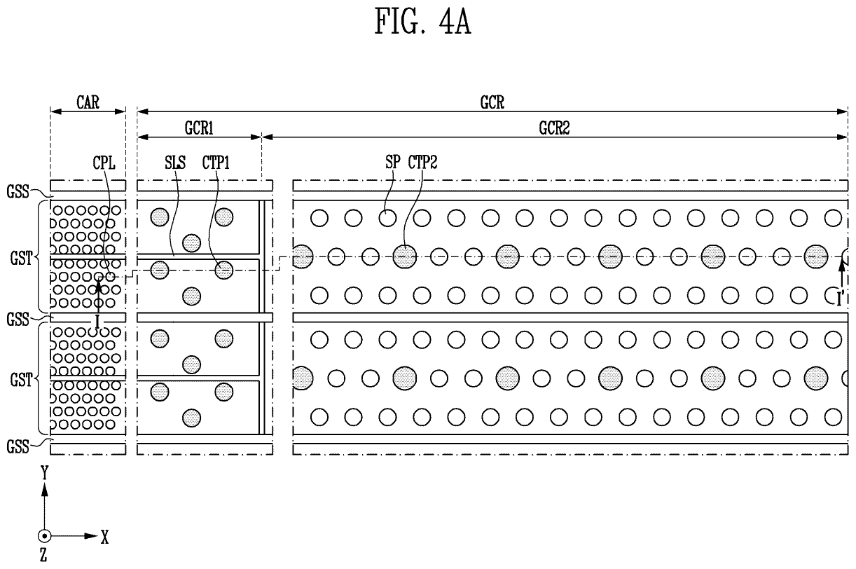

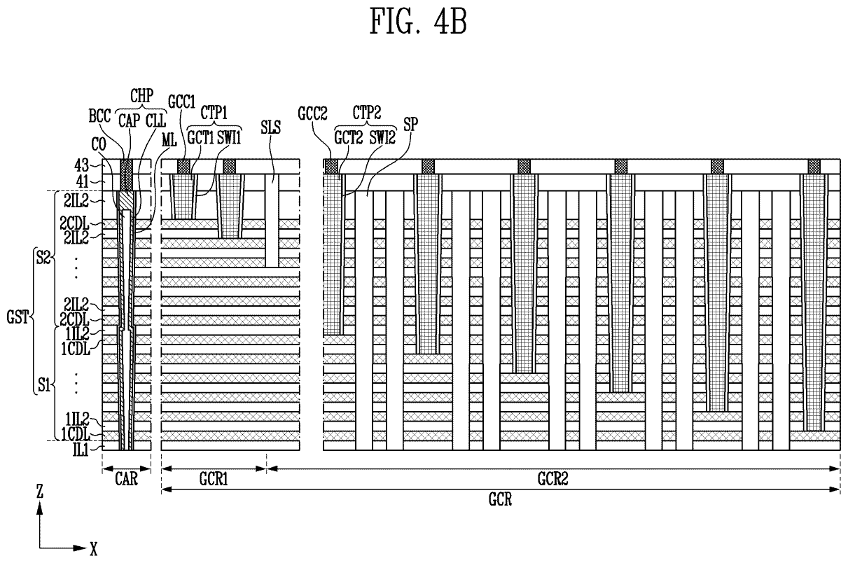

FIGS. 4A and 4B are a plan view and a cross-sectional view illustrating a semiconductor memory device according to an embodiment of the present disclosure.

Referring to FIG. 4A, each of the plurality of gate stacks GST may extend on the XY plane to overlap the cell array region CAR and the gate contact region GCR of the semiconductor substrate in the Z-axis direction. The plurality of cell pillars CPL and the plurality of contact pillars CTP1 and CPT2 extend in the Z-axis direction in the corresponding gate stack GST.

The plurality of cell pillars CPL may be arranged in a plurality of rows and a plurality of columns. Each row includes cell pillars arranged in line in the X-axis direction, and each column includes cell pillars arranged in line in the Y-axis direction. The plurality of rows may be divided into a plurality of groups by a select line separation structure SLS. In an embodiment, the plurality of cell pillars CPL may be divided into a first group of rows and a second group of rows by the select line separation structure SLS. The select line separation structure SLS is embedded in the gate stack GST and has a smaller length in the Z-axis direction than the gate separation structure GSS. Cell pillars in rows of different groups may be controlled on a group-by-group basis by select lines separated by the select line separation structure SLS. In an embodiment, the select line separation structure SLS may divide some of the plurality of conductive layers CDL shown in FIGS. 3A and 3B into the first drain select gate group DSG1 and the second drain select gate group DSG2, as shown in FIG. 2. For example, the cell pillars constituting the rows of the first group may correspond to the cell pillars of the first memory cell string CS1, as shown in FIG. 2, and they may be controlled by the drain select lines of the first drain select gate group DSG1, as shown in FIG. 2. The cell pillars constituting the rows of the second group may correspond to the cell pillars of the second memory cell string CS2, as shown in FIG. 2, and they may be controlled by the drain select lines of the second drain select gate group DSG2, as shown in FIG. 2.

The gate stack GST may include a first gate contact region GCR1 and a second gate contact region GRC2 extending along the XY plane from the first gate contact region GCR1. The first gate contact region GCR1 may be disposed between the cell array region CAR and the second gate contact region GRC2. The select line separation structure SLS may extend on a boundary between the first gate contact region GCR1 and the second gate contact region GRC2.

The plurality of contact pillars CTP1 and CTP2 may be divided into a plurality of first contact pillars CTP1 and a plurality of second contact pillars CPT2. The plurality of first contact pillars CTP1 are embedded in the gate stack GST in the first gate contact region GCR1, and the plurality of second contact pillars CTP2 are embedded in the gate stack GST in the second gate contact region GRC2.

A plurality of support pillars SP may be disposed around each second contact pillar CTP2. Each of the support pillars SP may extend in the Z-axis direction to penetrate the gate stack GST.

FIG. 4B is a cross-sectional view of a semiconductor memory device taken along line I-I′ shown in FIG. 4A.

Referring to FIGS. 4A and 4B, each cell pillar CPL and each support pillar SP penetrate through the first insulating layer IL1, the plurality of conductive layers 1CDL and 2CDL of the gate stack GST, and a plurality of second insulating layers 1IL2 and 2IL2 of the gate stack GPS.

The support pillar SP may include an insulating material.

The cell pillar CPL includes the memory layer ML and the channel pillar CHP.

The memory layer ML is disposed between the channel pillar CHP and the gate stack GST. The memory layer ML may include a tunnel insulating layer extending along a sidewall of the channel pillar CHP, a data storage layer disposed between the tunnel insulating layer and the gate stack GST, and a blocking insulating layer disposed between the data storage layer and the gate stack GST. The tunnel insulating layer may include an oxide, such as silicon dioxide (SiO₂). The blocking insulating layer may include an oxide, such as silicon dioxide (SiO₂), a high-k dielectric insulating material having a higher dielectric constant than silicon dioxide, or the like. The high-k dielectric insulating material may include an aluminum oxide layer, a hafnium oxide layer, or the like. The data storage layer may include a material layer capable of storing data which is changed by using Fowler-Nordheim tunneling. In an embodiment, the data storage layer may include a charge trap insulating layer, a floating gate layer, or an insulating layer including conductive nanodots. The charge trap insulating layer may include a silicon nitride layer. The data storage layer including the floating gate layer may be separated into a plurality of data storage patterns. The plurality of data storage patterns may be spaced apart from each other in the Z-axis direction, which is a stacking direction of the first insulating layer IL1, the plurality of conductive layers 1CDL and 2CDL, and the plurality of second insulating layers 1IL2 and 2IL2. The plurality of data storage patterns may be respectively disposed at levels at which the plurality of conductive layers 1CDL and 2CDL are disposed. The data storage layer including the charge trap insulating layer or the insulating layer including the conductive nanodots may be separated into a plurality of data storage patterns as described above, or may extend continuously in the Z-axis direction.

Each channel pillar CHP may include a channel layer CLL. The channel layer CLL may include a semiconductor material, such as silicon (Si), germanium (Ge), or a mixture thereof which serves as a channel region of a memory cell string. The channel layer CLL may have a tubular shape. The channel pillar CHP may further include a core insulating layer CO and a capping pattern CAP disposed in a central region of the tubular shape including the channel layer CLL. The capping pattern CAP may include a semiconductor layer doped with conductive impurities. The conductive impurities may include n-type impurities, or n-type impurities and p-type impurities. In an embodiment, the capping pattern CAP may include n-type doped silicon including n-type impurities as majority carriers.

The gate stack GST may include a plurality of sub-stacks successively arranged in the Z-axis direction. In an embodiment, the gate stack GST may include a first sub-stack S1 over the first insulating layer IL1 and a second sub-stack S2 over the first sub-stack S1. The plurality of conductive layers 1CDL and 2CDL may be divided into a plurality of first sub-conductive layers 1CDL of the first sub-stack S1 and a plurality of second sub-conductive layers 2CDL of the second sub-stack S2, and the plurality of the second insulating layers 1IL2 and 2IL2 may be divided into a plurality of first sub-second insulating layers 1IL2 and a plurality of second sub-second insulating layers 2IL2 of the first sub-stack S1.

Each of the memory layer ML and the channel layer CLL may have a corner portion formed in the vicinity of an interface between a plurality of sub-layers. In an embodiment, each of the memory layer ML and the channel layer CLL may have a corner formed in the vicinity of an interface between the first sub-stack S1 and the second sub-stack S2.

The upper surface of the gate stack GST opposite to the first insulating layer IL1 may be covered by a third insulating layer 41.

The select line separation structure SLS may penetrate the third insulating layer 41 and extend into the gate stack GST. The select line separation structure SLS may include an insulator. The select line separation structure SLS may be formed at a depth which penetrates the conductive layers provided as drain select lines among the plurality of conductive layers 1CDL and 2CDL and does not penetrate the conductive layer provided as a word line.

A gate contact plug GCT1 or GCT2 and a sidewall insulating layer SWI1 or SWI2 of each of the plurality of first contact pillars CTP1 and the plurality of second contact pillars CPT2 may penetrate the third insulating layer 41 and extend into the gate stack GST. The plurality of first contact pillars CTP1 are coupled to the plurality of drain select lines partitioned by the select line separation structure SLS, respectively. In the Z-axis direction, the plurality of second contact pillars CTP2 have a greater depth toward the first insulating layer IL1 than the plurality of first contact pillars CPT1. The plurality of second contact pillars CTP2 may be formed at different depths toward the first insulating layer IL1 in an opposite direction to the Z-axis direction to be respectively coupled to the other conductive layers except for the conductive layers provided as drain select lines among the plurality of conductive layers 1CDL and 2CDL.

The upper surface of the third insulating layer 41 opposite to the gate stack GST may be covered by the fourth insulating layer 43.

The bit line connection structure BCC may include a conductive material coupled to the channel pillar CHP through the third insulating layer 41 and the fourth insulating layer 43. The fourth insulating layer 43 may be penetrated by a first gate contact connection structure GCC1 and a second gate contact connection structure GCC2 including a conductive material. The first gate contact connection structure GCC1 is coupled to the first gate contact plug GCT1 of the corresponding first gate contact pillar CTP1. The second gate contact connection structure GCC2 is coupled to the second gate contact plug GCT2 of the corresponding second gate contact pillar CTP2.

As described above, the plurality of second contact pillars CTP2 have a greater depth toward the first insulating layer IL1 in the Z-axis direction than the plurality of first contact pillars CPT1. The second contact pillars CTP2 have different aspect ratios.

Hereinafter, embodiments of a manufacturing method for providing a semiconductor memory device as shown in FIGS. 4A and 4B are described.

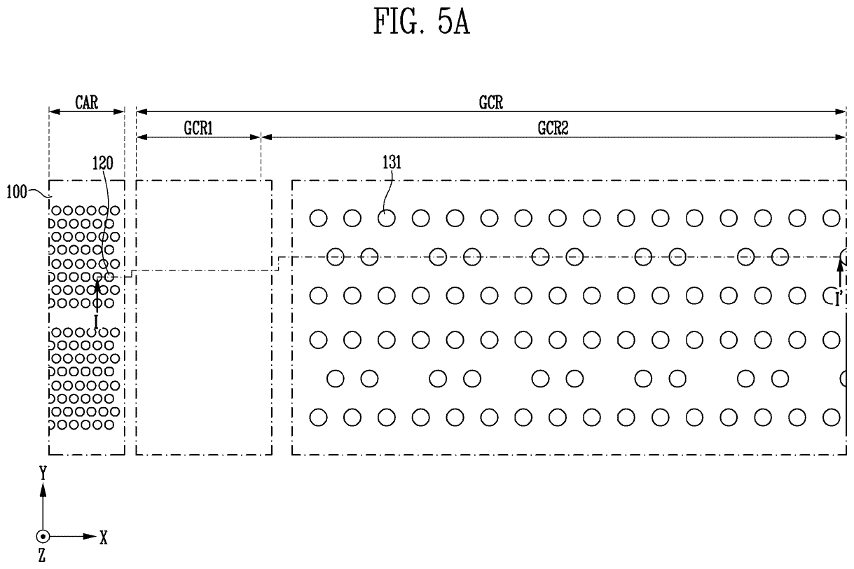

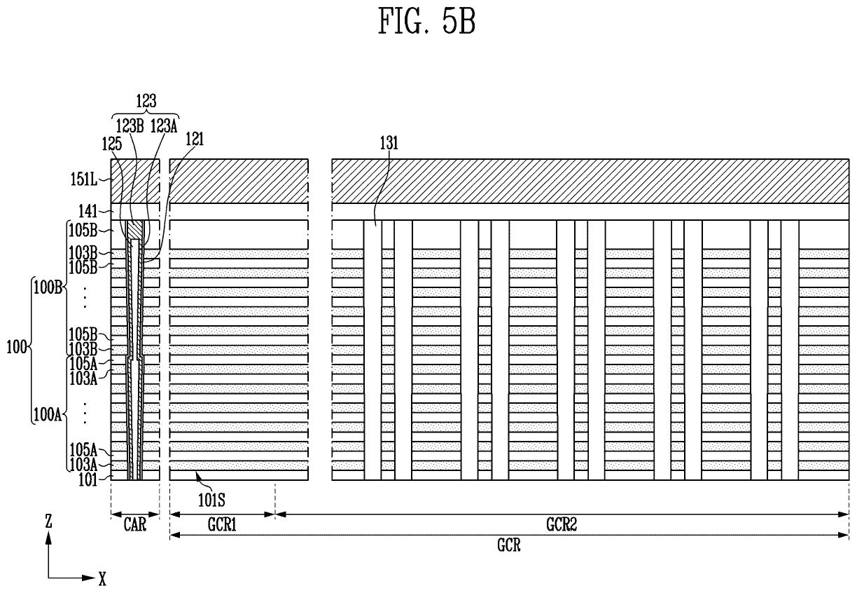

FIGS. 5A and 5B are a plan view and a cross-sectional view showing a preliminary stack, a cell pillar, and a mask layer according to an embodiment of the present disclosure.

Referring to FIGS. 5A and 5B, a first insulating layer 101 and a preliminary stack 100 may be formed over a lower structure (not shown). Though not shown, according to an embodiment, the lower structure may include the semiconductor substrate SUB including the plurality of transistors PTR, as shown in FIG. 3A, and the doped semiconductor structure DPS, as shown in FIG. 3A. In another embodiment, the lower structure may be a sacrificial substrate including a silicon wafer or the like. The sacrificial substrate may be replaced with the doped semiconductor structure DPS, as shown in FIG. 3B, in subsequent processes.

The first insulating layer 101 may include an insulating material, such as a silicon oxide layer or a silicon oxynitride layer. The first insulating layer 101 may include a surface 101S extending on the XY plane and facing the Z-axis direction. The first insulating layer 101 may include the cell array region CAR and the gate contact region GCR extending from the cell array region CAR. The gate contact region GCR may include the first gate contact region GRC1 and the second gate contact region GCC2. The first gate contact region GCR1 may be disposed between the cell array region CAR and the second gate contact region GRC2.

The preliminary stack 100 may include a plurality of first material layers and a plurality of second material layers different from the plurality of first material layers. In an embodiment, the plurality of first material layers may include a plurality of sacrificial layers 103A and 103B having an etching selectivity with respect to the first insulating layer 101, and the plurality of second material layers may include a plurality of second insulating layers 105A and 105B. In an embodiment, the first insulating layer 101 and the plurality of second insulating layers 105A and 105B may include an insulating material, such as a silicon oxide layer or a silicon oxynitride layer, and the plurality of sacrificial layers 103A and 103B may include a sacrificial insulating material, such as a silicon nitride layer. The plurality of sacrificial layers 103A and 103B and the plurality of second insulating layers 105A and 105B may be stacked in the Z-axis direction in which the surface 101S of the first insulating layer 101 faces. The plurality of sacrificial layers 103A and 103B and the plurality of second insulating layers 105A and 105B may be disposed alternately with each other in the Z-axis direction which is the stacking direction.

The cell array region CAR of the first insulating layer 101 and a partial region of the preliminary stack 100 on the cell array region CAR may be penetrated by a plurality of cell pillars 120. Each cell pillar 120 is disposed in a channel hole penetrating the preliminary stack 100 and the first insulating layer 101. In an embodiment, the channel hole may be provided by performing processes of forming a plurality of sub-holes so that the plurality of sub-holes may be coupled to each other. For example, the process of forming the channel hole may include forming a lower stack 100A of the preliminary stack 100, forming a first sub-hole penetrating the lower stack 100A and the first insulating layer 101, forming a filling structure in the first sub-hole, forming an upper stack 100B of the preliminary stack 100 over the lower stack 100A so that the filling structure may be covered, forming a second sub-hole penetrating the upper stack 100B and aligned on the filling structure, and removing the filling structure so that the first sub-hole may be opened. The plurality of sacrificial layers 103A and 103B may be divided into first sub-sacrifice layers 103A of the lower stack 100A and the second sub-sacrificial layers 103B of the upper stack 100B, and the plurality of second insulating layers 105A and 105B of the preliminary stack 100 may be divided into first sub-second insulating layers 105A of the lower stack 100A and second sub-second insulating layers 105B of the upper stack 100B. The first sub-hole penetrates the first sub-sacrifice layers 103A and the first sub-second insulating layers 105A, and the second sub-hole penetrates the second sub-sacrificial layers 103B and the second sub-second insulating layers 105B.

The process of forming the plurality of cell pillars 120 includes a process of forming a memory layer 121 on an inner wall of the channel hole and a process of forming a channel pillar 123 in the channel hole. The memory layer 121 may include the blocking insulating layer, the data storage layer, and the tunnel insulating layer as described with reference to FIGS. 4A and 4B. The channel pillar 123 is formed in the central region of the channel hole opened by the memory layer 121. In an embodiment, forming the channel pillar 123 may include forming a channel layer 123A on an inner wall of the memory layer 121, and filling a central region of a tubular structure formed by the channel layer 123A with a core insulating layer 125 and a capping pattern 123B. The channel layer 123A may include a semiconductor material, such as silicon (Si), germanium (Ge), or a mixture thereof, which serves as a channel region. The capping pattern 123B may include a doped semiconductor layer.

The preliminary stack 100 is penetrated by a plurality of support pillars 131. In an embodiment, the plurality of support pillars 131 may pass through the second gate contact region GCR2 of the first insulating layer 101 and extend in the Z-axis direction to pass through the preliminary stack 100. In an embodiment, the plurality of support pillars 131 may include an insulating material. Embodiments of the present disclosure are not limited thereto, and each support pillar 131 may be provided by using the process of forming the channel hole and the process of forming the cell pillar 120, and may be configured in the same manner as the cell pillar 120.

FIG. 5B is a cross-sectional view of the preliminary stack 100 taken along line I-I′ of FIG. 5A.

Referring to FIG. 5B, the preliminary stack 100 penetrated by the memory layer 121, the channel pillar 123, and the plurality of support pillars 131 may be covered by the third insulating layer 131. The third insulating layer 131 may include an insulating material, such as a silicon oxide layer or a silicon oxynitride layer.

Subsequently, a mask layer 151L may be formed over the third insulating layer 131. The mask layer 151L has an etching selectivity with respect to the first insulating layer 101, the plurality of sacrificial layers 103A and 103B, the plurality of second insulating layers 105A and 105B, and the third insulating layer 131. In an embodiment, the mask layer 151L may include a silicon layer.

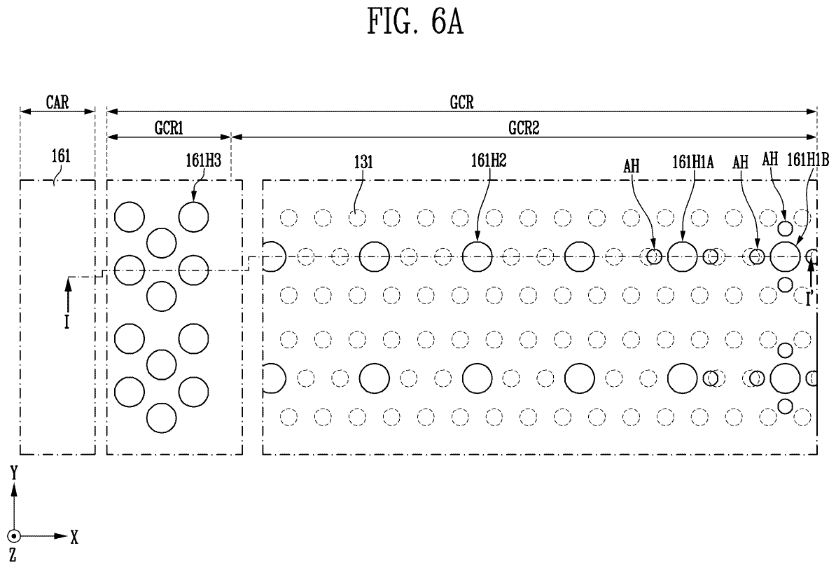

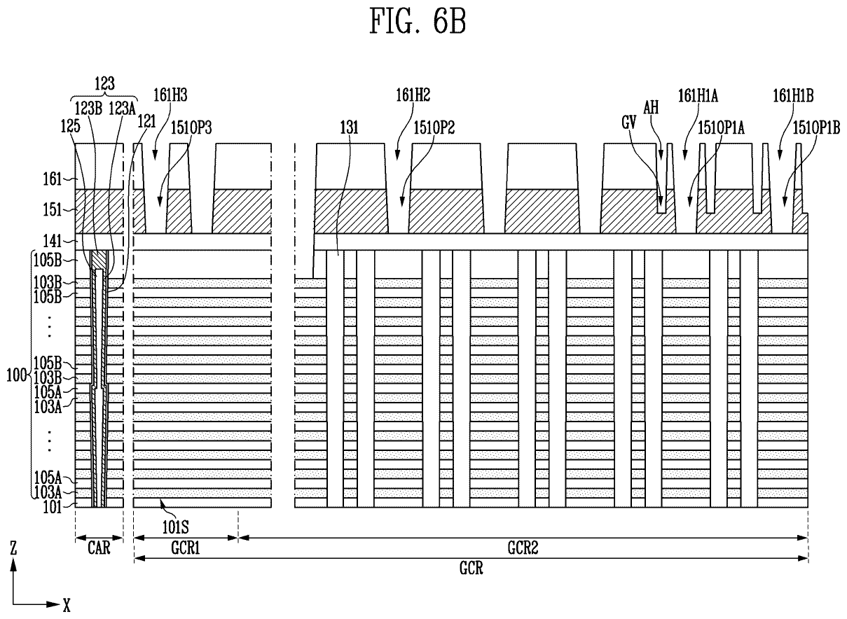

FIGS. 6A and 6B are a plan view and a cross-sectional view showing a first photoresist pattern and a mask pattern according to an embodiment of the present disclosure.

Referring to FIGS. 6A and 6B, a first photoresist pattern 161 is formed over the mask layer 151L, as shown in FIG. 5B. The first photoresist pattern 161 has a plurality of etching holes 161H1A, 161H1B, 161H2, and 161H3 and a plurality of auxiliary holes AH. The plurality of etching holes 161H1A, 161H1B, 161H2, and 161H3 and the plurality of auxiliary holes AH overlap the gate contact region GCR of the first insulating layer 101. In the XY plane, each of the plurality of auxiliary holes AH and the plurality of etching holes 161H1A, 161H1B, 161H2, and 161H3 may have a cross-sectional structure with various shapes including a polygon, such as a rectangle or a square, an ellipse, a circle, and a semi-circle. In the XY plane, each of the plurality of auxiliary holes AH is narrower than each of the plurality of etching holes 161H1A, 161H1B, 161H2, and 161H3.

The plurality of etching holes 161H1A, 161H1B, 161H2, and 161H3 may include a plurality of first etching holes 161H1A and 161H1B, a plurality of second etching holes 161H2, and a plurality of third etching holes 161H3. The plurality of third etching holes 161H3 overlap the first gate contact region GCR1 of the first insulating layer 101, and the plurality of first etching holes 161H1A and 161H1B and the plurality of second etching holes 161H2 overlap the second gate contact region GCR2 of the first insulating layer 101. The plurality of first etching holes 161H1A and 161H1B may be divided into a first group of the first etching holes 161H1A and a second group of the first etching holes 161H1B.

The plurality of auxiliary holes AH may be disposed around the plurality of first etching holes 161H1A and 161H1B. More auxiliary holes AH are disposed around the first etching holes 161H1B in the second group than around the first etching holes 161H1A in the first group. In an embodiment, two auxiliary holes AH may be disposed around each first etching hole 161H1A in the first group, and four auxiliary holes AH may be disposed around each first etching hole 161H2B in each second group.

FIG. 6B is a cross-sectional view of the first photoresist pattern 161 and the mask pattern 151 taken along line I-I′ of FIG. 6A.

Referring to FIG. 6B, a mask pattern 151 is formed by etching some regions of the mask layer 151L, as shown in FIG. 5B, by using the first photoresist pattern 161 as an etching barrier. The mask pattern 151 has a plurality of grooves GV and a plurality of openings 151OP1A, 151OP1B, 151OP2, and 151OP3. The plurality of grooves GV are formed by etching areas of the mask layer corresponding to the plurality of auxiliary holes AH, and the plurality of openings 151OP1A, 151OP1B, 151OP2, and 151OP3 are formed by etching the areas of the mask layer corresponding to the plurality of etching holes 161H1A, 161H1B, 161H2, and 161H3. Accordingly, in the XY plane, each of the plurality of grooves GV is narrower than each of the plurality of openings 151OP1A, 151OP1B, 151OP2, and 151OP3.

Because the plurality of etching holes 161H1A, 161H1B, 161H2, and 161H3 are wider than the plurality of auxiliary holes AH, an etching depth of regions of the mask layer corresponding to the plurality of etching hole 161H1A, 161H1B, 161H2, and 161H3 during the etching of the mask layer is greater than that of the mask layer corresponding to the plurality of auxiliary hole AH. The etching process of the mask layer may be controlled so that the plurality of openings 151OP1A, 151OP1B, 151OP2, and 151OP3 may have a depth which completely penetrates the mask layer, and a bottom surface of each of the plurality of grooves GV may be disposed in the mask layer. Accordingly, the third insulating layer 141 may be exposed through the plurality of openings 151OP1A, 151OP1B, 151OP2, and 151OP3, and a part of the mask layer may be interposed between the plurality of grooves GV and the third insulating layer 241.

During the etching of the mask layer, an upper end of each of the plurality of auxiliary holes AH may be spaced apart from an upper end of the first etching hole 161H1A or 161H1B adjacent thereto.

The plurality of openings 151OP1A, 151OP1B, 151OP2, and 151OP3 may include a plurality of first openings 151OP1A, 151OP1B, a plurality of second openings 151OP2, and a plurality of third openings 151OP3. The plurality of first openings 151OP1A and 151OP1B are divided into a first group of the first openings 151OP1A corresponding to the first group of the first etching holes 161H1A and a second group of the first opening 151OP1B corresponding to the second group of the first etching hole 161H1B. The plurality of second openings 151OP2 respectively correspond to the plurality of second etching holes 161H2. The plurality of first openings 151OP1A and 151OP1B and the plurality of second openings 151OP2 overlap the second gate contact region GCR2 of the first insulating layer 101. The plurality of third openings 151OP3 correspond to the plurality of third etching holes 161H3, respectively, and overlap the first gate contact region GCR1 of the first insulating layer 101.

The plurality of grooves GV may be disposed around the plurality of first openings 151OP1A and 151OP1B. More grooves GV are disposed around the first openings 151OP1B in the second group than around the first openings 151OP1A in the first group.

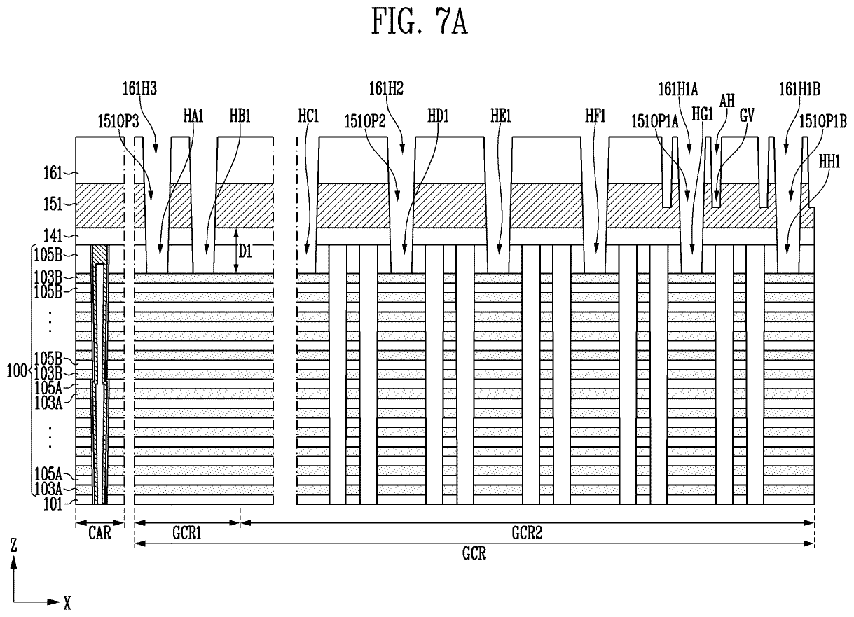

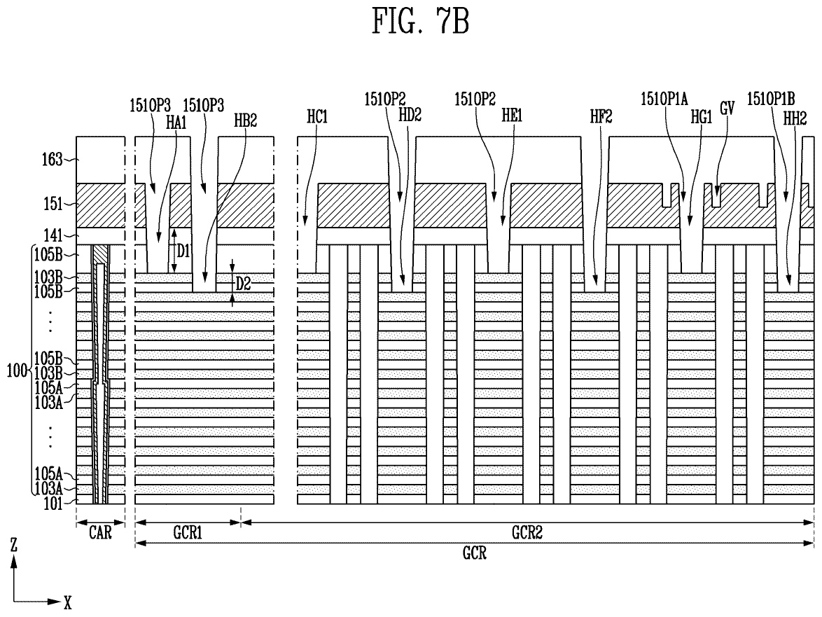

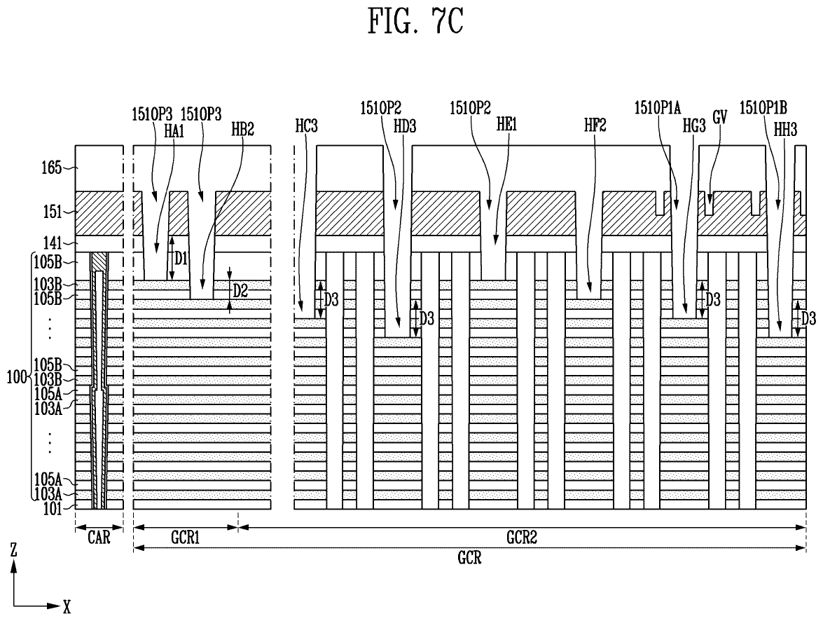

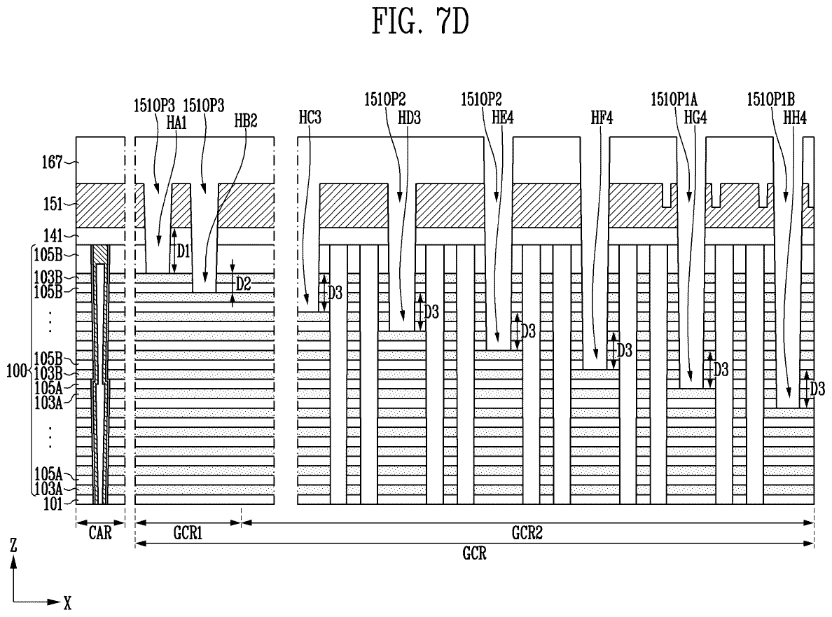

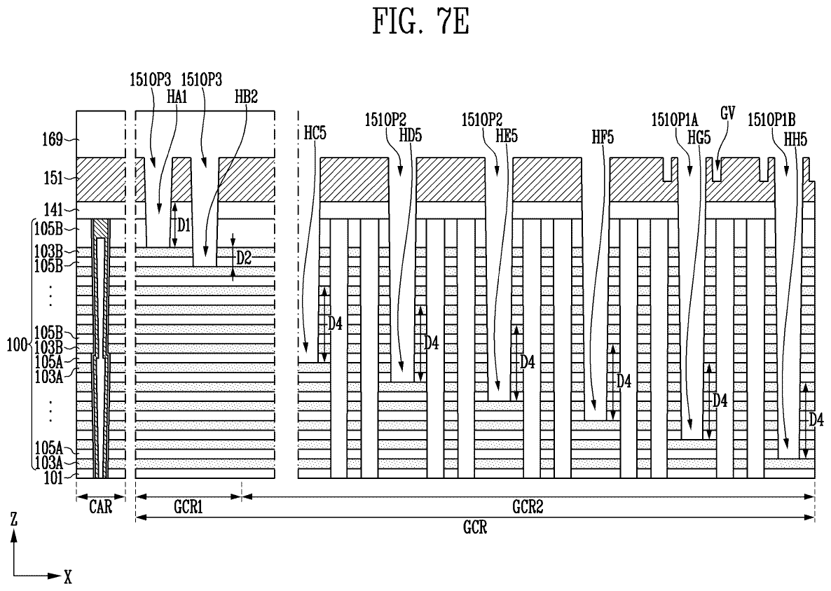

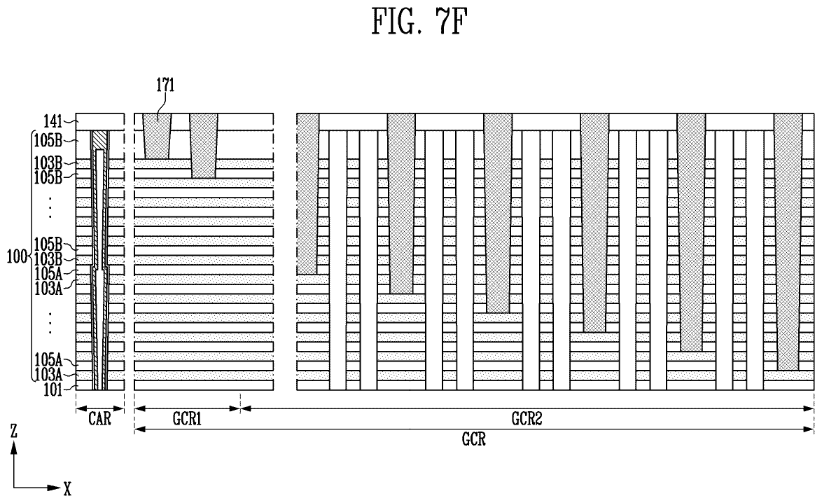

FIGS. 7A, 7B, 7C, 7D, 7E, and 7F are cross-sectional views illustrating a plurality of holes and a plurality of sacrificial pillars according to an embodiment of the present disclosure.

Referring to FIG. 7A, a third insulating layer 141 and a part of the preliminary stack 100 may be etched so that an uppermost sacrificial layer among the plurality of sacrificial layers 103A and 103B of the preliminary stack 100 may be exposed through a first etching process. The first etching process may be performed by introducing etching gas through the plurality of first openings 151OP1A and 151OP1B, the plurality of second openings 151OP2, and the plurality of third openings 151OP3 as described with reference to FIG. 6B. An uppermost second insulating layer among the plurality of second insulating layers 105A and 105B of the preliminary stack 100 may be etched by the first etching process.

Through the first etching process, a first group of a plurality of holes HA1, HB1, HC1, HD1, HE1, HF1, HG1, and HH1 may be formed to have a first depth D1 toward the first insulating layer 101 in the Z-axis direction. Each hole may have the first depth D1 to pass through the third insulating layer 141 and the uppermost second insulating layer of the preliminary stack 100. The plurality of holes HA1, HB1, HC1, HD1, HE1, HF1, HG1, and HH1 of the first group include a first contact hole HA1 and first preliminary holes HB1, HC1 HD1, HE1 HF1, HG1 and HH1.

Referring to FIG. 7B, after the first photoresist pattern 161, as shown in FIG. 7A, is removed, a second photoresist patterns 163 may be formed. The second photoresist pattern 163 may open the first opening 151OP1B in the second group, at least one of the plurality of second openings 151OP2, and at least one of the plurality of third openings 151OP3, and may fill and block the first opening 151OP1A in the first group, the other second openings 151OP2, the other third openings 151OP3, and the plurality of grooves GV. Some of the first preliminary holes HB1, HC1, HD1, HE1, HF1, HG1, and HH1, as shown in FIG. 7A, and the first contact hole HA1 are filled by the second photoresist pattern 163, and the other first preliminary holes (e.g., HB1, HD1, HF1, and HH1 shown in FIG. 7A) are opened.

Subsequently, the preliminary stack 100 is etched by a second etching process using the second photoresist pattern 163 as an etching barrier. The second etching process may be performed by introducing etching gas through the first preliminary holes (e.g., HB1, HD1, HF1, and HH1 shown in FIG. 7A) opened by the second photoresist pattern 163. The second etching process is performed so that the uppermost sacrificial layer among the plurality of sacrificial layers 103A and 103B of the preliminary stack 100 may be penetrated. According to an embodiment, through the second etching process, the preliminary stack 100 may be etched to a second etching depth D2 toward the first insulating layer 101 in the Z-axis direction. The preliminary stack 100 may be etched to the second etching depth D2 to penetrate the uppermost sacrificial layer (the uppermost layer among the plurality of sacrificial layers 103A and 103B) and the lower second insulating layer (the second sacrificial layer 105B under the uppermost sacrificial layer among 105A and 105B).

Through the second etching process, a second contact hole HB2 and a plurality of second preliminary holes HD2, HF2, and HH2 are formed to have a greater depth than the first depth D1 toward the first insulating layer 101 in the Z-axis direction.

Referring to FIG. 7C, after the second photoresist pattern 163, as shown in FIG. 7B, is removed, a third photoresist patterns 165 may be formed. The third photoresist pattern 165 may open the plurality of first openings 151OP1A and 151OP1B, some of the plurality of second openings 151OP2, and some of the plurality of third openings, which are not shown in FIG. 7C, and may fill and block the other second openings 151OP2, the other third openings 151OP3, and the plurality of grooves GV. The third photoresist pattern 165 fills some (HF2) of the plurality of second preliminary holes HD2, HF2, and HH2, as shown in FIG. 7B, and opens the others (HD2 and HH2). Some (HE1) of the first preliminary holes HC1, HE1, and HG1, as shown in FIG. 7B, are filled by the third photoresist pattern 165, and the others (HC1 and HG1) are opened. The first contact hole HA1 and the second contact hole HB2 are filled by the third photoresist pattern 165.

Subsequently, the preliminary stack 100 is etched by a third etching process using the third photoresist pattern 165 as an etching barrier. The third etching process may be performed by introducing etching gas through the first preliminary holes (e.g., HC1 and HG1 shown in FIG. 7B) opened by the third photoresist pattern 165 and the second preliminary holes HD2 and HH2 opened by the third photoresist pattern 165. The third etching process may be performed by etching the preliminary stack 100 to a third etching depth D3 toward the first insulating layer 101 in the Z-axis direction so that two layers of the sacrificial layers 103A and 103B and two layers of the second insulating layers 105A and 105B may be further penetrated.

Through the third etching process, a plurality of third preliminary holes HC3, HD3, HG3, and HH3 may be formed to have a depth greater than that of the second contact hole HB2 toward the first insulating layer 101 in the Z-axis direction.

Referring to FIG. 7D, after the third photoresist pattern 165, as shown in FIG. 7C, is removed, a fourth photoresist pattern 167 may be formed. The fourth photoresist pattern 167 may open the plurality of first openings 151OP1A and 151OP1B, some of the plurality of second openings 151OP2, and some of the plurality of third openings, which are not shown in FIG. 7C, and may fill and block the other second openings 151OP2, the other third openings 151OP3, and the plurality of grooves GV. The fourth photoresist pattern 167 fills some (HC3 and HD3) of the third preliminary holes HC3, HD3, HG3, and HH3, as shown in FIG. 7C, and opens the others (HG3 and HH3). The first and second preliminary holes HE1 and HF2, the first contact hole HA1, and the second contact hole HB2, as shown in FIG. 7C, are filled by the third photoresist pattern 165.

Subsequently, the preliminary stack 100 is etched by a fourth etching process using the fourth photoresist pattern 167 as an etching barrier. The fourth etching process may be performed by introducing etching gas through the third preliminary holes HG3 and HH3, as shown in FIG. 7C, opened by the fourth photoresist pattern 167 and the first and second preliminary holes HE1 and HF2, as shown in FIG. 7C, opened by the fourth photoresist pattern 167. The fourth etching process may be performed by etching the preliminary stack 100 to the third etching depth D3 toward the first insulating layer 101 in the Z-axis direction so that two layers of the sacrificial layers 103A and 103B and two layers of the second insulating layers 105A and 105B may be further penetrated.

Through the fourth etching process, a plurality of fourth preliminary holes HE4, HF4, HG4, and HH4 may be formed to have a depth greater than that of the third preliminary holes HC3 and HD3 toward the first insulating layer 101 in the Z-axis direction.

A plurality of holes in a second group respectively corresponding to the plurality of first openings 151OP1A and 151OP1B, the plurality of second openings 151OP2, and the plurality of third openings 151OP3 formed through the above-described second to fourth etching processes may be formed at different depths toward the first insulating layer 101 in an opposite direction to the Z-axis direction. The plurality of holes in the second group include a plurality of first holes respectively corresponding to the plurality of first openings 151OP1A and 151OP1B, a plurality of second holes respectively corresponding to the plurality of second openings 151OP2, and a plurality of third holes respectively corresponding to the plurality of third openings 151OP3. The plurality of first holes include the fourth preliminary holes HG4 and HH4, the plurality of second holes include the third preliminary holes HC3 and HD3 and the fourth preliminary holes HE4 and HF4, and the plurality of third holes include the first contact hole HA1 and the second contact hole HB2. The fourth preliminary holes HG4 and HH4 of the plurality of first holes and the third preliminary holes HC3 and the fourth preliminary holes HE4 and HF4 and HD3 of the plurality of second holes have a greater depth toward the first insulating layer 101 than the first contact hole HA1 and the second contact hole HB2 of the plurality of the second holes. The fourth preliminary holes HG4 and HH4 of the plurality of first holes have a greater depth toward the first insulating layer 101 than the third preliminary holes HC3 and HD3 and the fourth preliminary holes HE4 and HF4 of the plurality of second holes. The fourth preliminary hole HH4 corresponding to the first opening 151OP1B in the second group have a greater depth toward the first insulating layer 101 than the fourth preliminary hole HG4 corresponding to the second opening 151OP1A in the first group.

Referring to FIG. 7E, after the fourth photoresist pattern 167, as shown in FIG. 7D, is removed, a fifth photoresist patterns 169 may be formed. The fifth photoresist pattern 169 may open the plurality of first openings 151OP1A and 151OP1B, the plurality of second openings 151OP2, and the plurality of grooves GV, and may fill and block the plurality of third openings 151OP3. The fifth photoresist pattern 169 may open some of the plurality of holes HA1, HB2, HC3, HD3, HE4, HF4, HG4, and HH4 of the second group, as shown in FIG. 7D, and may block the others. In an embodiment, the third preliminary holes HC3 and HD3 and the fourth preliminary holes HE4, HF4, HG4, and HH4, as shown in FIG. 7D, may be opened by the fifth photoresist pattern 169, and the first contact hole HA1 and the second contact hole HA1, HB2 may be blocked by the fifth photoresist pattern 169.

A fifth etching process may be performed by introducing etching gas through the plurality of first openings 151OP1A and 151OP1B and the plurality of second openings 151OP2 in a state in which the plurality of grooves GV are opened.

The fifth etching process is performed so that a lowermost sacrificial layer (the lowermost layer among the sacrificial layers 103A and 103B) may be exposed. The fifth etching process may be performed by etching the preliminary stack 100 toward the first insulating layer 101 in the Z-axis direction to an etching depth greater than that in each of the first to fourth etching processes. According to an embodiment, the fifth etching process may be performed by etching the preliminary stack 100 to a fourth etching depth D4 so that four sacrificial layers among the plurality of sacrificial layers 103A and 103B and two second insulating layers among the plurality of second insulating layers 105A and 105B may be further etched.

Through the fifth etching process, a plurality of holes HC5, HD5, HE5, HF5, HG5, and HH5 of a third group may formed to have a depth greater than that of the fourth preliminary holes HG4 and HH4 of the plurality of first holes, the third preliminary holes HC3 and HD3 and the fourth preliminary holes HE4 and HF4 of the plurality of second holes, as shown in FIG. 7D, toward the first insulating layer 101 in the Z-axis direction. The plurality of holes HC5, HD5, HE5, HF5, HG5, and HH5 of the third group are a plurality of third contact holes which have a greater depth than the first contact hole HA1 and the second contact hole HB2 and have different depths.

The etching rate at the bottom of the hole may be significantly lower in the fifth etching process which is performed at a greater etching depth than the first to fourth etching processes. Particularly, the larger the aspect ratio of the hole, the lower the ion energy reaching the bottom of the hole. According to an embodiment of the present disclosure, by forming the plurality of grooves GV around the first openings 151OP1A and 151OP1B corresponding to holes having a large aspect ratio, the inflow of etching gas may be increased, so that the reduction in the ion energy reaching the bottom surface of the hole having a high aspect ratio may be compensated. Accordingly, according to an embodiment of the present disclosure, even when holes having different aspect ratios are formed at a great depth at the same time, it is possible to stably provide the holes with different aspect ratios at a target depth.

Referring to FIG. 7F, after the fifth photoresist pattern 169 is removed to open the first contact hole HA1 and the second contact hole HA2, as shown in FIG. 7E, the plurality of holes HC5, HD5, HE5, HF5, HG5, and HH5 in the third group are filled with a plurality of sacrificial pillars 171, respectively. Each sacrificial pillar 171 has an etching selectivity with respect to the plurality of sacrificial layers 103A and 103B and the plurality of second insulating layers 105A and 105B. In an embodiment, the sacrificial pillar 171 may include an amorphous carbon layer.

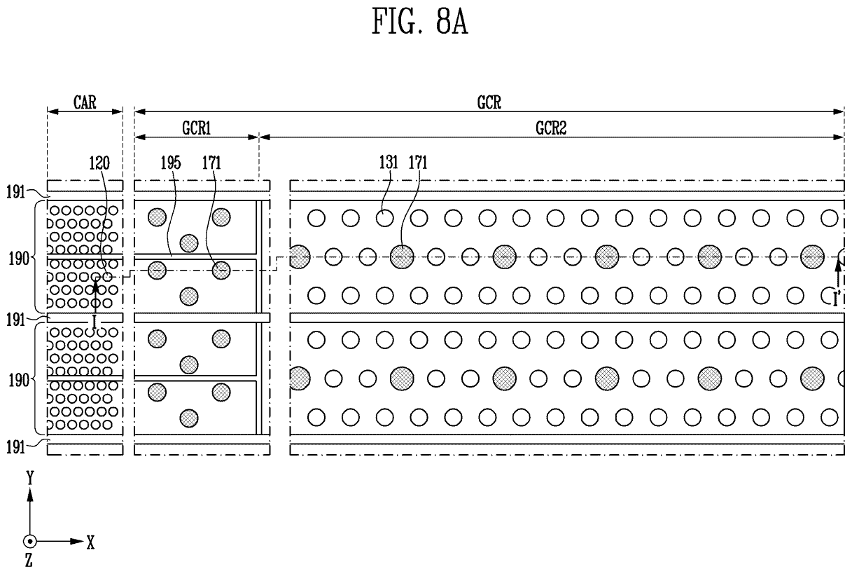

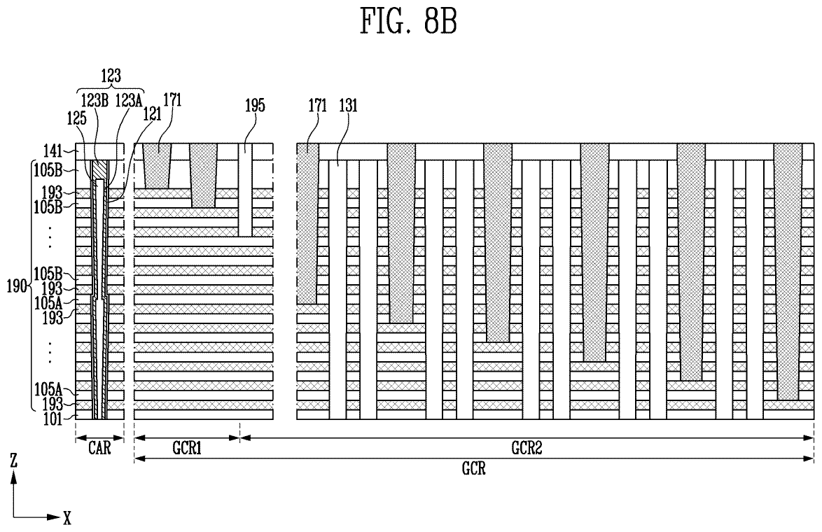

FIGS. 8A and 8B are a plan view and a cross-sectional view showing a gate stack according to an embodiment of the present disclosure. FIG. 8B is a cross-sectional view of a gate stack taken along line I-I′ of FIG. 8A.

Referring to FIGS. 8A and 8B, a slit 191 is formed through the preliminary stack 100, as shown in FIG. 7F. Subsequently, the plurality of sacrificial layers 103A and 103B of the preliminary stack 100, as shown in FIG. 7F, may be replaced with a plurality of conductive layers 193 through the slit 191. As a result, a gate stack 190 may be formed. The plurality of support pillars 131, the plurality of cell pillars 120, and the plurality of sacrificial pillars 171 may serve as support structures when the plurality of sacrificial layers 103A and 103B, as shown in FIG. 7F, are replaced with the plurality of conductive layers 193.

After the gate stack 190 is formed, the slit 191 may be filled with a filler. As a result, the gate separation structure GSS as described with reference to FIG. 4A may be provided.

Thereafter, a select line separation structure 195 which passes through some of the plurality of conductive layers 193 may be formed.

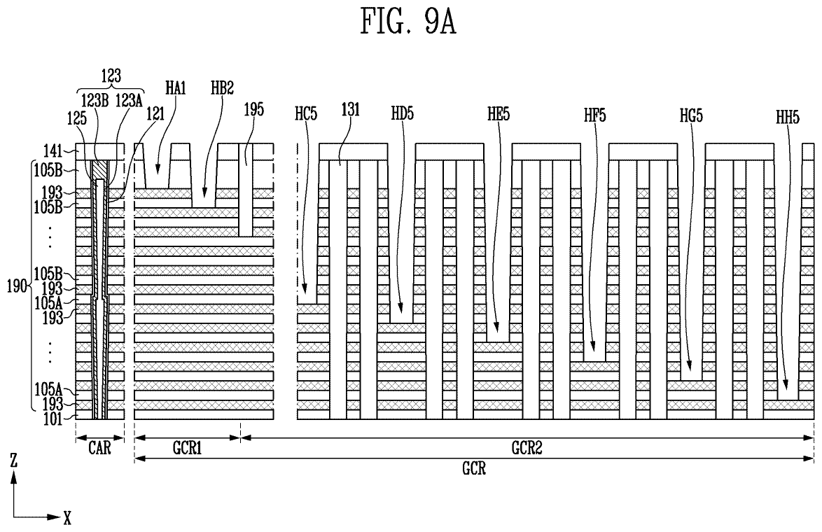

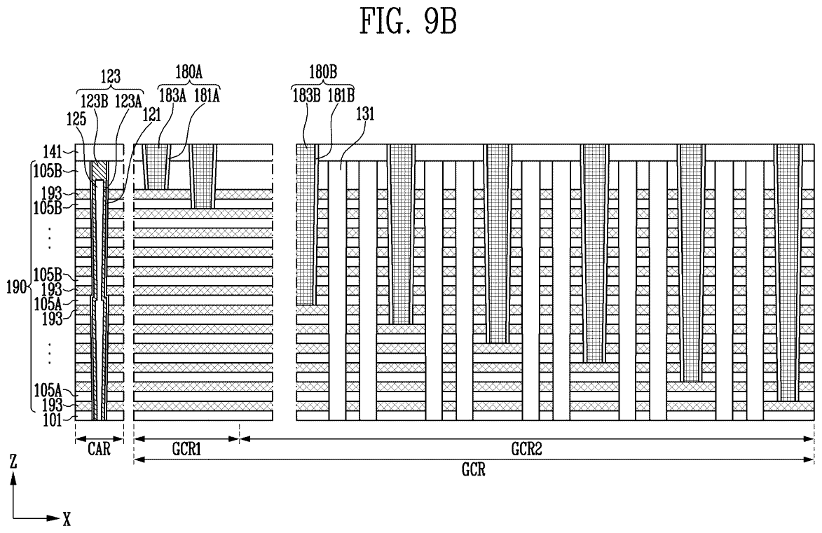

FIGS. 9A and 9B are cross-sectional views illustrating a plurality of contact holes and a plurality of contact pillars according to an embodiment of the present disclosure.

Referring to FIG. 9A, the plurality of sacrificial pillars 171, as shown in FIG. 8B, may be removed to expose the plurality of conductive layers 193. As a result, the first contact hole HA1, the second contact hole HB2, and the plurality of holes HC5, HD5, HE5, HF5, HG5, and HH5 of the third group, which are the plurality of third contact holes, may be opened.

Referring to FIG. 9B, a first contact pillar 180A may be formed in each of the first contact hole HA1 and the second contact hole HB2, as shown in FIG. 9A, and a second contact pillar 180B may be formed in the plurality of holes HC5, HD5, HE5, HF5, HG5, and HH5 of the third group, as shown in FIG. 9A. The process of forming the first contact pillar 180A and the second contact pillar 180B may include a process of forming a sidewall insulating layer 181A or 181B on a sidewall of each of the first contact hole HA1, the second contact hole HB2, and the plurality of holes HC5, HD5, HE5, HF5, HG5, and HH5 in the third group, as shown in FIG. 9A, and a process of forming a gate contact plug 183A or 183B by filling a central region of each of the first contact hole HA1, the second contact hole HB2 and the plurality of the holes HC5 and HD5, HE6, HF6, HG6, and HH6 in the third group, as shown in FIG. 9A, with a conductive material. The gate contact plug 183A or 183B includes a bottom surface in contact with a corresponding one of the plurality of conductive layers 193, and it is insulated from the other conductive layers by the sidewall insulating layer 181A or 181B.

After the first contact pillar 180A and the second contact pillar 180B are formed, subsequent processes, such as forming the fourth insulating layer 43, as shown in FIG. 4B, and forming the bit line connection structure BCC and the first and second gate contact connection structures GCC1 and GCC2 passing through the fourth insulating layer 430, as shown in FIG. 4B, may be performed.

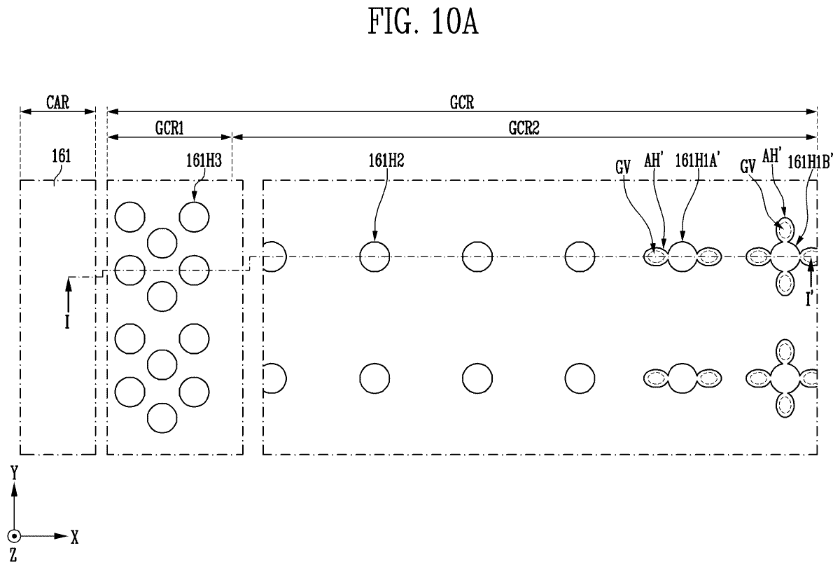

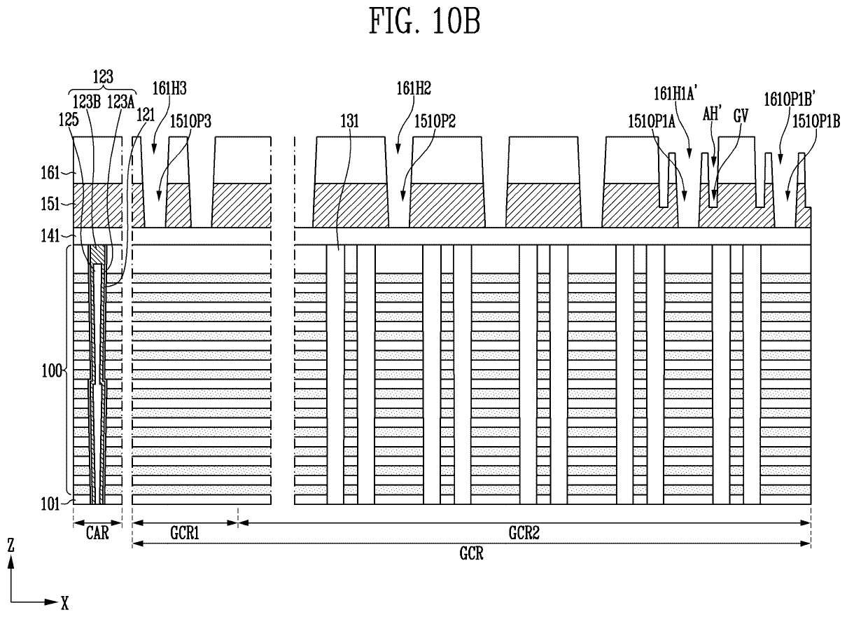

FIGS. 10A and 10B are a plan view and a cross-sectional view showing a first photoresist pattern and a mask pattern according to an embodiment of the present disclosure. FIG. 10B is a cross-sectional view of the first photoresist pattern 161 and the mask pattern 151 taken along line I-I′ of FIG. 10A.

Referring to FIGS. 10A and 10B, the first photoresist pattern 161 is disposed over the mask layer after the first insulating layer 101, the preliminary stack 100, the memory layer 121, the channel layer 123A, and the capping pattern 123B of the channel pillar 123, the core insulating layer 125, the third insulating layer 141, and the mask layer (151L shown in FIG. 5B) as described with reference to FIGS. 5A and 5B are formed. As described above with reference to FIGS. 6A and 6B, the first photoresist pattern 161 includes a plurality of first etching holes 161H1A′ and 161H1B′, the plurality of second etching holes 161H2, the plurality of third etching holes 161H3, and the plurality of auxiliary holes AH′. In the XY plane, the plurality of auxiliary holes AH′ may have a smaller area than each of the plurality of first etching holes 161H1A′ and 161H1B′, the plurality of second etching holes 161H2, and the plurality of third etching holes 161H3, and may have a shape having a major axis facing the plurality of first etching holes 161H1A′ and 161H1B′ and a minor axis intersecting the major axis. According to an embodiment, in the XY plane, each of the plurality of auxiliary holes AH′ may have an elliptical or rectangular cross-sectional structure having a major axis facing the first etching hole 161H1A′ or 161H1B′ adjacent thereto and a minor axis orthogonal to the major axis.

Subsequently, the mask pattern 151 is formed by etching some regions of the mask layer 151L, as shown in FIG. 5B, by using the first photoresist pattern 161 as an etching barrier. As described with reference to FIG. 6B, the mask pattern 151 has the plurality of grooves GV and the plurality of openings 151OP1A, 151OP1B, 151OP2, and 151OP3. During the etching of the mask layer, an upper end of each of the plurality of auxiliary holes AH′ and an upper end of the plurality of first etching holes 161H1A′ and 161H1B′ may extend on the XY plane. Accordingly, the upper end of each auxiliary hole AH′ may be coupled to the first etching hole 161H1A′ or 161H1B′ adjacent thereto.

Thereafter, the semiconductor memory device, as shown in FIGS. 4A and 4B, may be provided by performing the processes described with reference to FIGS. 7A to 7F, the processes described with reference to FIGS. 8A and 8B, and the processes described with reference to FIGS. 9A and 9B.

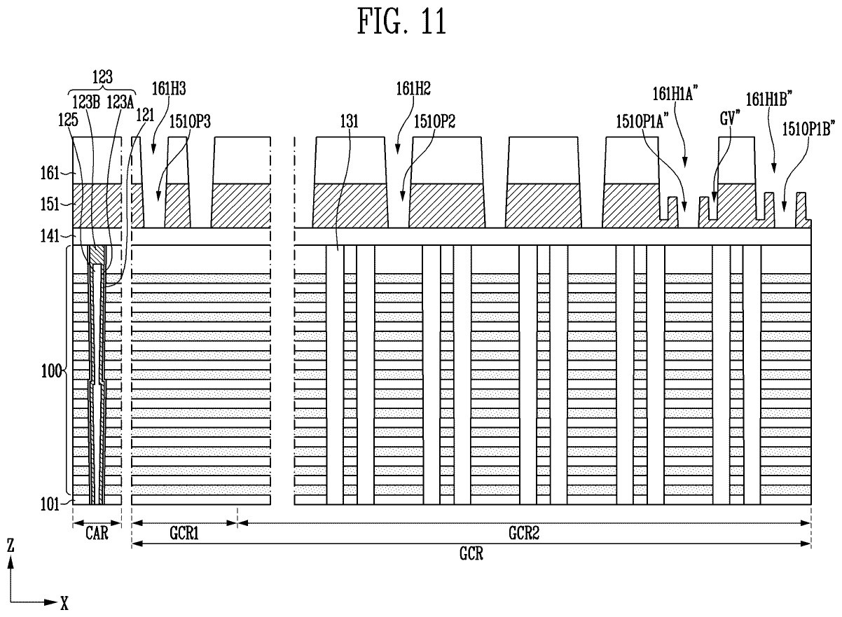

FIG. 11 is a cross-sectional view showing a first photoresist pattern and a mask pattern according to an embodiment of the present disclosure.

Referring to FIG. 11, the first photoresist pattern 161 is disposed over the mask layer after the first insulating layer 101, the preliminary stack 100, the memory layer 121, the channel layer 123A, and the capping pattern 123B of the channel pillar 123, the core insulating layer 125, the third insulating layer 141, and the mask layer (151L shown in FIG. 5B) as described with reference to FIGS. 5A and 5B are formed. As shown in FIGS. 10A and 10B, the first photoresist pattern 161 includes the plurality of first etching holes 161H1A′ and 161H1B′, the plurality of second etching holes 161H2, the plurality of third etching holes 161H3, and the plurality of auxiliary holes AH′.

Subsequently, the mask pattern 151 is formed by etching some regions of the mask layer 151L, as shown in FIG. 5B, by using the first photoresist pattern 161 as an etching barrier. As described with reference to FIG. 5B, the mask pattern 151 has a plurality of grooves GV″, a plurality of first openings 151OP1A″ and 151OP1B″, a plurality of second openings 151OP2, and a plurality of third openings 151OP3. During the etching of the mask layer, each of the plurality of auxiliary holes AH′, as shown in FIG. 10B, and the corresponding first etching hole 161H1A′ or 161H1B′ may be extended on the XY plane to be coupled to each other. Accordingly, the plurality of first etching holes 161H1A″ and 161H1B″ extended, as shown in FIG. 11, may be formed. During the etching of the mask layer, an upper end of each of the plurality of grooves GV″ and an upper end of the plurality of first openings 151OP1A″ and 151OP1B″ may be extended on the XY plane. Accordingly, the top of each groove GV″ may be coupled to the first opening 151OP1A″ or 151OP1B″ adjacent thereto.

Thereafter, the semiconductor memory device, as shown in FIGS. 4A and 4B, may be provided by performing the processes described with reference to FIGS. 7A to 7F, the processes described with reference to FIGS. 8A and 8B, and the processes described with reference to FIGS. 9A and 9B.

According to an embodiment of the present disclosure, an inflow amount of etching gas may be increased by using a groove disposed around an opening of a mask pattern.

According to an embodiment of the present disclosure, by controlling positions of grooves, holes having different aspect ratios are formed at the same time, so that a difference in etching rate may be reduced when the holes having the different aspect ratios are formed. Thus, the processes of forming the holes with different aspect ratios may be simplified and stabilized. In addition, the operational reliability of the semiconductor memory device may be improved by reducing defects in the holes with the different aspect ratios.

What is claimed is:

1. A method of manufacturing a semiconductor memory device, the method comprising:
forming a first insulating layer;
forming a preliminary stack by alternately stacking over a surface of the first insulating layer in a stacking direction second insulating layers of a plurality of second insulating layers with sacrificial layers of a plurality of sacrificial layers;
forming a mask pattern over the preliminary stack, the mask pattern including a plurality of first openings, a plurality of second openings, a plurality of third openings, and a plurality of grooves disposed around the plurality of first openings;
forming a first group of a plurality of holes exposing an uppermost sacrificial layer among the sacrificial layers by etching the preliminary stack through the plurality of first openings, the plurality of second openings, and the plurality of third openings;
forming a second group of a plurality of holes respectively corresponding to the plurality of first openings, the plurality of second openings, and the plurality of third openings, the plurality of holes in the second group having different depths toward the first insulating layer in an opposite direction to the stacking direction by repeatedly performing an etching process on the preliminary stack with the plurality of grooves blocked; and
forming a third group of a plurality of holes by etching the preliminary stack with the plurality of grooves opened and one or more of the plurality of holes in the second group opened through the plurality of first openings and the plurality of second openings.

2. The method of claim 1, wherein an etching depth of the preliminary stack toward the first insulating layer is greater when forming the plurality of holes in the third group than when repeatedly etching the preliminary stack.

3. The method of claim 1, wherein each of the plurality of grooves is narrower, as measured on a plane parallel to the surface of the first insulating layer, than each of the plurality of first openings, each of the plurality of second openings, and each of the plurality of third openings.

4. The method of claim 1, wherein repeatedly performing the etching process on the preliminary stack with the plurality of grooves blocked includes repeating an etching cycle at least twice, and
wherein the etching cycle includes:
forming a photoresist pattern over the mask pattern to fill the plurality of grooves and open at least one first opening among the plurality of first openings, at least one second opening among the plurality of second openings, and at least one third opening among the plurality of third openings;
etching the preliminary stack by using the photoresist pattern as an etching barrier to penetrate at least one sacrificial layer among the sacrificial layers; and
removing the photoresist pattern.

5. The method of claim 1, wherein the plurality of holes in the second group include a plurality of first holes corresponding to the plurality of first openings, a plurality of second holes corresponding to the plurality of second openings, and a plurality of third holes corresponding to the plurality of third openings,
wherein, in the opposite direction to the stacking direction, the plurality of first holes and the plurality of second holes have a greater depth toward the first insulating layer than the plurality of third holes, and
wherein, in the opposite direction to the stacking direction, the plurality of first holes have a greater depth toward the first insulating layer than the plurality of second holes.

6. The method of claim 5, wherein forming of the third group of the plurality of holes includes:
forming a photoresist pattern over the mask pattern to open the plurality of grooves, open the plurality of first holes, and open the plurality of second holes and fill the plurality of third holes;
etching the preliminary stack using the photoresist pattern as an etching barrier to expose a lowermost sacrificial layer among the sacrificial layers; and
removing the photoresist pattern.

7. The method of claim 5, wherein the plurality of first openings include a first group of a first opening and a second group of a first opening,
wherein the plurality of first holes include the first hole in the first group corresponding to the first opening in the first group, and the first hole in the second group corresponding to the first opening in the second group, the first hole in the second group having a greater depth toward the first insulating layer than the first hole in the first group in the opposite direction to the stacking direction, and
wherein a greater number of the plurality of grooves are disposed around the first opening in the second group than around the first opening in the first group.

8. The method of claim 1, wherein forming of the mask pattern over the preliminary stack includes:
forming a mask layer over the preliminary stack;
forming a photoresist pattern including the plurality of etching holes and a plurality of auxiliary holes over the mask layer; and
forming the plurality of first openings, the plurality of second openings, the plurality of third openings, and the plurality of grooves by etching regions of the mask layer corresponding to the etching holes and the plurality of auxiliary holes,
wherein the plurality of first openings, the plurality of second openings, and the plurality of third openings correspond to the plurality of etching holes, and
wherein grooves of the plurality of grooves correspond to auxiliary holes of the plurality of auxiliary holes.

9. The method of claim 8, wherein each of the auxiliary holes is narrower, as measured on a plane parallel to the surface of the first insulating layer, than each of the plurality of etching holes.

10. The method of claim 8, wherein an upper end of each of the auxiliary holes is spaced apart from an upper end of an adjacent etching hole among the plurality of etching holes.

11. The method of claim 8, wherein an upper end of each of the auxiliary holes is coupled to an adjacent etching hole among the plurality of etching holes when the regions of the mask layer corresponding to the plurality of etching holes and the plurality of auxiliary holes are etched.

12. The method of claim 8, wherein, when the regions of the mask layer corresponding to the plurality of etching holes and the plurality of auxiliary holes are etched,
each of the auxiliary holes and a corresponding etching hole among the plurality of etching holes are coupled to each other to form an extended etching hole, and
an upper end of each of the grooves is coupled to an adjacent etching hole among the plurality of first openings.

13. The method of claim 1, further comprising:
filling each of the plurality of holes in the third group with a sacrificial pillar;
forming a slit through the preliminary stack;
replacing the plurality of sacrificial layers with a plurality of conductive layers through the slit;
removing the plurality of sacrificial pillars to expose the plurality of conductive layers and open the plurality of holes in the third group;
forming a sidewall insulating layer on a sidewall of each of the plurality of holes in the third group; and
forming a plurality of gate contact plugs within the plurality of holes in the third group to be coupled to the plurality of conductive layers, respectively.

14. A method of manufacturing a semiconductor memory device, the method comprising:
forming an insulating layer;
forming a preliminary stack by alternately stacking first material layers of a plurality of first material layers with second material layers of a plurality of second material layers over a surface of the insulating layer in a stacking direction;
forming a mask pattern over the preliminary stack, the mask pattern including a first opening, a second opening, and a plurality of grooves disposed around the first opening;
forming a first hole and a second hole to different depths toward the insulating layer in a direction opposite to the stacking direction by etching the preliminary stack through the first opening and the second opening with the plurality of grooves blocked; and
etching the preliminary stack through the first hole and the second hole with the plurality of grooves, the first opening, and the second opening opened so that the first hole and the second hole are extended deeper toward the insulating layer.
